(19) United States
(12) Patent Application Publication
(10) Pub. No.: US 2010/0242837 A1
(43) Pub. Date: Sep. 30, 2010

(54) COMBINATORIAL DEPOSITION METHOD AND APPARATUS THEREOF

(76) Inventors: Masahiro GOTO, Tsukuba-shi (JP); Akira Kasahara, Tsukuba-shi (JP); Masahiro Tosa, Tsukuba-shi (JP)

Correspondence Address: WENDEROTH, LIND & PONACK, L.L.P., 1030 15th Street, N.W.,, Suite 400 East, Washington, DC, 20005-1503, US

(21) Appl. No.: 12/797,828

(22) Filed: Jun. 10, 2010

Related U.S. Application Data
(62) Division of application No. 12/554,299, filed on Sep. 4, 2009.
Application No. 12/554,299 is a continuation of application No. 10/553,848, filed on Dec. 14, 2005, now abandoned.

(30) Foreign Application Priority Data
May 10, 2004 (JP) 2004-139866

(51) Int. Cl. C23C 14/34; C23C 14/00

(52) U.S. Cl. 118/50; 204/298.07; 204/298.15

(57) ABSTRACT

A combinatorial deposition method is characterized in that, in a method of performing thin-film coating onto a substrate disposed in a vacuum, two or more substrates are moved between a deposition position and a cooling position, sequentially only substrates to be coated is moved to the deposition position while substrates at the cooling position are cooled by a cooling mechanism, and substrates are respectively deposited under different deposition conditions in only one vacuum evacuation process. Various deposition conditions with regard to sputtering and the like are accurately controlled, so that coating films can be efficiently produced under different deposition conditions.

### TECHNICAL FIELD

The present invention relates to a combinatorial deposition method and an apparatus thereof. More particularly, the invention relates to a combinatorial deposition method and an apparatus thereof in which various sputter deposition conditions can be accurately controlled, and coating films can be efficiently prepared under different deposition conditions.

### BACKGROUND ART

Thin film coating onto a substrate is one effective material development method for enhancing the excellent function of a substrate material, adding a new function, or further increasing the life of the substrate material, and it is now drawing attention for its application in industrial, biological, aerospace, and other various fields. For investigation of various thin layer compositions of such thin film coatings, a deposition apparatus using a combinatorial method, and a masking mechanism that can prepare a thin film in correspondence with a 3-dimensional diagram have been proposed (e.g. patent document 1), and thus thin film composition that can generate new properties can be efficiently found.

On the other hand, for the investigation of thin film conditions, experiments and evaluations of many kinds of deposition conditions are needed in which a large number of deposition condition parameters are changed little by little. Thus, the best conditions have not been able to be determined without tremendous labor, time and other difficulties. For example, in thin film coating prepared by sputtering, properties of obtained coating films are largely influenced by many deposition condition parameters such as sputter gas pressure, gas type, partial pressure, sputter power value, substrate temperature, distance between the substrate and a target, and sample bias, in addition to the composition and combination of sputter materials. Therefore, although experiments are need in which each of the deposition condition parameters is changed for determining the best conditions, actually in most cases evaluation has been conducted on experiments where only one or two kinds of deposition condition parameters are changed. Accordingly, it is highly unlikely that the deposition conditions have been optimized with regard to all the various properties of the obtained coating films.

Patent document 1: JP-A-2004-035983.

However, if the thin film coating were performed under many deposition conditions whose parameters are accurately controlled, and characteristics of the coating films are evaluated, the best deposition conditions that optimize each of the properties of the coating films could be determined. Therefore, a deposition method and an apparatus in which the parameters can be controlled accurately and efficiently are desired.

Thus, the subject of the invention of the application, which was made in the light of the above circumstances, is to provide a method and an apparatus thereof, in which the problems in the conventional art are solved, many deposition condition parameters of sputter coating and the like can be accurately controlled, and many kinds of coating films under different deposition conditions are produced efficiently with the parameters being changed little by little. Such combinatorial deposition is realized, thereby the optimum conditions of each of the properties (frictional property, electrical conductivity, optical property, thermal property and the like) of the coating films can be easily determined, which is extremely useful for developing a new material.

### DISCLOSURE OF THE INVENTION

To solve the above problems, first, the present invention provides a combinatorial deposition method characterized in that, in a method for performing the thin-film coating onto a substrate disposed in vacuum, two or more substrates can be moved to a deposition position or a cooling position, and in one vacuum evacuation process, while substrates are held at the cooling position where the substrates are cooled by a cooling mechanism, only objective substrates to be coated are sequentially moved to the deposition position and subjected to deposition.

Second, the present invention provides a combinatorial deposition method characterized in that the deposition is performed to two or more substrates with the deposition conditions different for each substrate; third, it provides a combinatorial deposition method characterized in that the two or more substrates can be moved to the deposition position or the cooling position by a rotation mechanism; fourth, it provides a combinatorial deposition method characterized in that a water- or liquid nitrogen-cooling mechanism is adopted; fifth, it provides a combinatorial deposition method characterized in that the deposition is performed by sputtering with any one or more of the following deposition conditions: sputter gas pressure, sputter gas, partial pressure, sputter power value, substrate temperature, distance between a substrate and a target, and sample bias, and the conditions are different for each substrate in one vacuum evacuation process.

Furthermore, sixth, the invention of the present application provides a combinatorial deposition apparatus characterized in that the apparatus performs thin-film coating onto the substrate disposed in a vacuum, wherein a sample holder can hold two or more substrates, and each substrate can be moved to a deposition position or a cooling position, and in one vacuum evacuation process, while substrates at the cooling position are cooled by the cooling mechanism, only objective substrates to be coated are sequentially moved to the deposition position and subjected to deposition.

Moreover, seventh, the invention of the application provides a combinatorial deposition apparatus characterized in that the deposition is performed on the two or more substrates with the deposition conditions different for each substrate; eighth, it provides a combinatorial deposition apparatus characterized in that the two or more substrates can be moved to the deposition position or the cooling position by a rotation mechanism; ninth, it provides a combinatorial deposition apparatus characterized in that even if the substrate at the deposition position is heated to 1000° C. or more, the rise in temperature in the substrates at the cooling position can be restrained within 100 K; tenth, it provides combinatorial deposition apparatus characterized in that a water- or liquid nitrogen-cooling mechanism is adopted as a cooling mechanism; eleventh, it provides combinatorial deposition apparatus characterized in that the apparatus is for deposition by sputtering, wherein in one vacuum evacuation process, deposition can be performed for two or more substrates by varying any one or more of the following deposition conditions: sputter gas pressure, sputter gas type, partial pressure, sputter power value, substrate temperature, distance between a substrate and a target, and sample bias; twelfth, it provides combinatorial deposition apparatus characterized in that a valve for controlling sputter gas pressure is provided and a feedback mechanism changing conductance so as to control the sputter gas pressure at a prescribed value is provided; thirteenth, it provides combinatorial deposition apparatus characterized in that the distance between the substrate and the target can be controlled by a straight-line introducing mechanism; fourteenth, it provides a combinatorial deposition apparatus characterized in that a turbo molecular pump is provided as a vacuum evacuation mechanism; fifteenth, it provides a combinatorial deposition apparatus characterized in that a substrate for Suzuki-type friction test can be mounted; and sixteenth, it provides a combinatorial deposition apparatus characterized in that a position of the sample holder or a sputter source is variable, and deposition can be performed for a substrate cooled by the cooling mechanism.

In addition, seventeenth, the invention of the application provides a sample holder characterized in that the sample holder has a rotation mechanism that can hold two or more samples, wherein while a sample not to be subjected to deposition is cooled at the cooling position by the cooling mechanism, only a sample to be subjected to deposition is subjected to temperature control at the deposition position; eighteenth, it provides a sample holder characterized in that even if the substrate at the deposition position is heated to 1000° C. or more, the rise in temperature of the substrates at the cooling position can be restrained within 100° K.; and nineteenth, it provides a sample holder characterized in that a water- or liquid nitrogen-cooling mechanism is adopted as the cooling mechanism.

### BRIEF DESCRIPTION OF THE DRAWINGS

FIG. 1 is a view schematically illustrating a general configuration of a combinatorial coating apparatus of the invention of the application;

FIG. 2 is a graph illustrating change in friction coefficient of a thin film deposited with different substrate temperature using a combinatorial coating apparatus of the invention of the application; and

FIG. 3 is a graph illustrating change in friction coefficient of a thin film deposited with different oxygen partial pressure using a combinatorial coating apparatus of the invention of the application.

### REFERENCES IN THE FIGURES INDICATE AS FOLLOWS

1 chamber,
2 sample holder,
3 sputter source,
4 evacuation system,
5 inert-gas supply port,
6 reactive-gas supply port,
7 heater,
8 cooling mechanism,
9 valve,
11 view port, and
21 substrate.

### DETAILED DESCRIPTION OF THE INVENTION

The invention of the present application has the aforementioned features, and hereinafter, several embodiments are described. The most distinctive feature is that, in the invention of the application, deposition can be performed under various deposition conditions in one vacuum evacuation process. Accordingly, deposition according to a combinatorial manner in which many deposition conditions are changed little by little can be realized accurately and simply.

A combinatorial deposition method of the invention of the present application is characterized in that in a method of thin film coating a substrate disposed in a vacuum, it is possible for two or more substrates to be moved to the deposition position or the cooling position, and in one vacuum evacuation process, only objective substrates to be coated are sequentially moved to the deposition position and subjected to deposition, while the substrates at the cooling position are cooled by the cooling mechanism.

As the method of thin film coating onto the substrate disposed in a vacuum, to which the combinatorial deposition method of the present invention is applied, various known deposition methods including physical vapor deposition (PVD) such as sputter or vacuum evaporation, and chemical vapor deposition (CVD) such as thermal decomposition reaction, reactive evaporation and chemical transport, can be used. More specifically, for example, magnetron sputter, molecular beam epitaxy, or pulse laser evaporation can be considered.

In the combinatorial deposition method of the application, to perform the deposition for two or more substrates, each substrate can be moved to a deposition position or a cooling position. Then, in one vacuum evacuation process, only objective substrates to be coated are sequentially moved to the deposition position and subjected to the deposition while the substrates at the cooling position are cooled by the cooling mechanism. The number of substrates is not particularly limited, and can be appropriately determined in consideration of substrate size, size of apparatus for deposition, the number of deposition conditions and the like. As moving means of the two or more substrates, which is not particularly limited, various mechanisms and structures can be considered. For example, a moving means using a rotation mechanism such as turntable, a belt conveyer, and further a moving means having an up-and-down function can be exemplified. In addition, a cooling mechanism is not particularly limited, and for example, cooling using a refrigerant such as liquid nitrogen, liquid helium, or water can be exemplified. In particular, in the invention of the application, a water cooling mechanism with water circulation or liquid-nitrogen cooling mechanism is simple and preferable.

For the substrate at the deposition position, substrate temperature can be controlled according to deposition conditions. Specifically, for example, the substrate can be subjected to deposition while being heated, or the substrate can be subjected to deposition without heating, or the substrate can be also subjected to deposition while being cooled.

In this way, deposition is sequentially performed for only objective substrates to be coated, while other substrates are cooled, so that deposition can be performed for two or more substrates in one vacuum evacuation process. In deposition, deposition conditions can be changed for each substrate. Thus, in one vacuum evacuation process, deposition according to a combinatorial manner in which many deposition conditions are changed little by little can be realized.

More specifically, for example, regarding deposition by sputtering, in the combinatorial deposition method of the invention of the application, deposition can be performed for many substrates with varying any one or more of the following deposition conditions in one vacuum evacuation process: sputter gas pressure, sputter gas type, partial pressure, sputter power value, substrate temperature, distance between a substrate and a target.

The combinatorial deposition method as above can be simply realized by a combinatorial deposition apparatus provided by the invention of the application. Thus, the combinatorial deposition apparatus of the invention of the application is characterized in that the apparatus is for performing thin film coating for the substrates disposed in vacuum, wherein a sample holder can hold two or more substrates and move each substrate to a deposition position or a cooling position, and only objective substrates to be coated are sequentially moved to the deposition position and subjected to the deposition while the substrates at the cooling position are cooled by the cooling mechanism, in one vacuum evacuation process.

The combinatorial deposition apparatus of the invention of the application have various configurations according to various thin-film coating methods, but the sample holder is distinctive. In the sample holder, two or more substrates can be held and each substrate can be moved to a deposition position or a cooling position. The number of substrates that can be held is not particularly limited, and can be appropriately determined in consideration of the size of a substrate, size of an apparatus for deposition, the number of deposition conditions and the like. The sample holder is exchangeable according to conditions such as a substrate. A moving means of two or more substrates is not particularly limited, and various mechanisms and structures can be considered. For example, a moving means using a rotation mechanism such as a turntable, a belt conveyer, or a moving means having an up-and-down function can be exemplified. In the invention of the application, it is simple and preferable that two or more substrates can be moved to a deposition position or a cooling position by a rotation mechanism. Moreover, a cooling mechanism is not particularly limited, and for example, cooling using a refrigerant such as liquid nitrogen, liquid helium, or water can be exemplified. In the invention of the application, a water cooling mechanism with water circulation or a liquid nitrogen cooling mechanism is illustrated as a simple and preferable example.

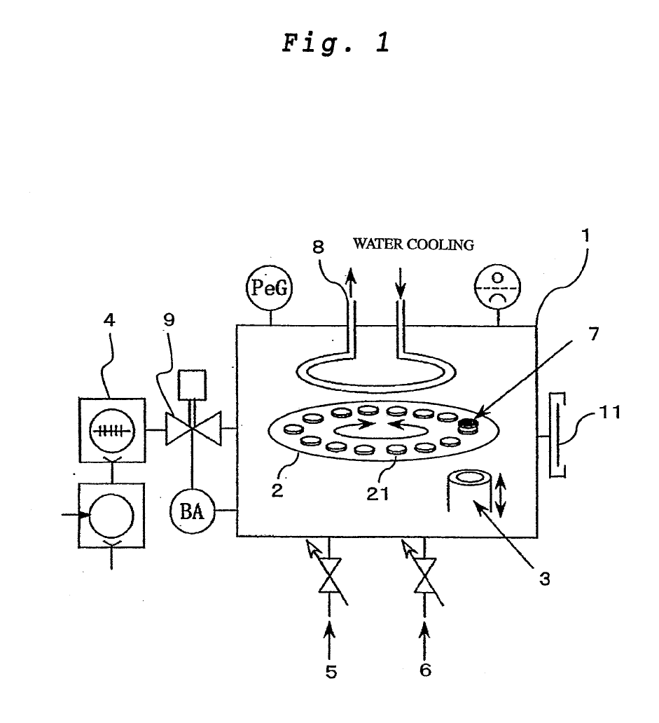

Thus, for example, a sample holder provided by the invention of the application is characterized in that the sample holder has a rotation mechanism that can hold two or more samples, wherein it is possible for samples not to be coated to be cooled by a cooling mechanism at a cooling position, and for only samples to be coated to be subjected to temperature control at a deposition position. More specifically, for example, as illustrated in FIG. 1, a sample holder (2) has a turntable, and substrates (21) are disposed on the turntable in an approximately circular pattern. Near a deposition position, a heater (7) for heating is arranged and near cooling positions, a cooling mechanism (8) with a cooling pipe is arranged, so that temperature of the substrate (21) at the deposition position can be controlled to a desired deposition temperature and then subjected to the deposition while substrates (21) at the cooling position are cooled. According to the configuration, for example, even if the substrate (21) at the deposition position is heated to 1000° C. or more, the rise in temperature of the substrates (21) at the cooling position can be restrained within 100 K. Moreover, since the substrate (21) can be moved between the deposition position and the cooling position by rotating the turntable, only the substrate (21) that is moved to the deposition position is sequentially subject to deposition. Thus, deposition can be performed by varying deposition conditions for each substrate (21). Therefore, the sample holder (2) of the invention of the application makes it possible to perform deposition according to a combinatorial manner in various thin-film coating method.

For example, a combinatorial deposition apparatus provided by the invention of the application may be for deposition by sputtering, wherein deposition can be performed for two or more substrates by varying any one or more of the following deposition conditions: sputter gas pressure, sputter gas, partial pressure, sputter power value, substrate temperature, distance between a substrate and a target, and sample bias, in one vacuum evacuation process. The sputtering deposition apparatus may be, for example, illustrated in FIG. 1, in which a sample holder (2) and a sputter source (3) are installed in a chamber (1), and a vacuum evacuation mechanism (4) and supply ports (5), (6) for inert gas and reactive gas are provided. In such a combinatorial deposition apparatus, a valve (9) for controlling sputter gas pressure may have a feedback function for changing conductance so that the pressure becomes a prescribed value. Sputter gas pressure can be set accurately and reproducibly. The distance between the substrate (21) and a target can be controlled by the straight-line introducing mechanism for the sputter source (3). Furthermore, a turbo molecular pump and the like are provided as the vacuum evacuation mechanism (4), so that, for example, in a vacuum system of the apparatus, ultra high vacuum of about 10⁻⁵ Pa can be realized in a shorter time. The sample holder (2) is configured so that a substrate (21) suited for the Suzuki friction test can be mounted, and thus various property evaluation of coating thin-films produced can be performed more simply.

The combinatorial deposition apparatus of the invention of the application is further characterized in that a position of the sample holder (2) or the sputter source (3) is variable and deposition can be performed for a substrate (21) cooled by the cooling mechanism (8). Thus, for example, by arranging a deposition position near the cooling mechanism (8) and by changing a position of the sample holder (2) or the sputter source (3), deposition can be performed for a substrate (21) while being cooled.

According to the invention of the present application, by changing various deposition conditions are changed little by little, many coating thin-films different in natures such as crystallinity and crystal orientation can be manufactured efficiently. And by evaluating various properties such as frictional properties, electrical conductivity, optical properties, and thermal properties of the various obtained coatings, many deposition condition parameters can be optimized more simply and surely and possibility of development of a new functional coating film is remarkably expanded.

Hereinafter, an embodiment of the invention of the application is further described in detail. It goes without saying that the invention is not limited to the following example and various modifications are possible.

### EXAMPLE

FIG. 1 is a view schematically illustrating a general configuration of an example of a combinatorial coating apparatus of the invention of the application. The combinatorial coating apparatus is a deposition apparatus using magnetron sputter and is composed of a main chamber (1), a multi-sample holder (2) and a sputter source (3) built in the main chamber (1), a vacuum evacuation system (4) connected to the main chamber (1), an inert-gas supply port (5), a reactive-gas supply port (6) and the like. A view port (11) of ICF305 size is provided at a front of the main chamber (1), and thus the multi-sample holder (2) can be efficiently taken in and out. Regarding the sputter gun (3), a position can be changed using a straight-line introducing mechanism (not shown), so that the distance between the substrate (21) to be deposited and the target can be controlled. The vacuum evacuation system (4) has a turbo molecular pump having throughput of 600 l/s, which can perform vacuum evacuation of 10⁻⁵ Pa in a short time. Regarding a valve (9) for communicating between the main chamber (1) and the vacuum evacuation system (4), opening and closing can be controlled by feedback that conductance is varied so that a prescribed pressure is attained, and thereby accurate setting of the sputter gas pressure can be achieved repeatedly.

A plural number of substrates (21), 14 in the case of FIG. 1, can be mounted on the multi-sample holder (2) and can be sequentially moved by rotation using the rotation mechanism. A substrate (21) to be deposited is moved to a deposition position near a heater (7) and the other 13 substrates (21) are disposed at a cooling position near a water cooling mechanism (8). Even if the substrate (21) to be deposited is heated to approximately 1000° C. by the heater (7), the other 13 samples are cooled by the cooling mechanism (8), so that the rise in temperature of these samples can be restrained within 100 K and only the objective substrate (21) can be deposited. According to such a configuration, deposition conditions can be accurately varied for each substrate (21) and, for example, 14 kinds of deposition conditions are realized in one vacuum evacuation process. Since the multi-sample holder (2) can be mounted with a substrate suited for the Suzuki friction test, property tests of coating films deposited can be efficiently conducted.

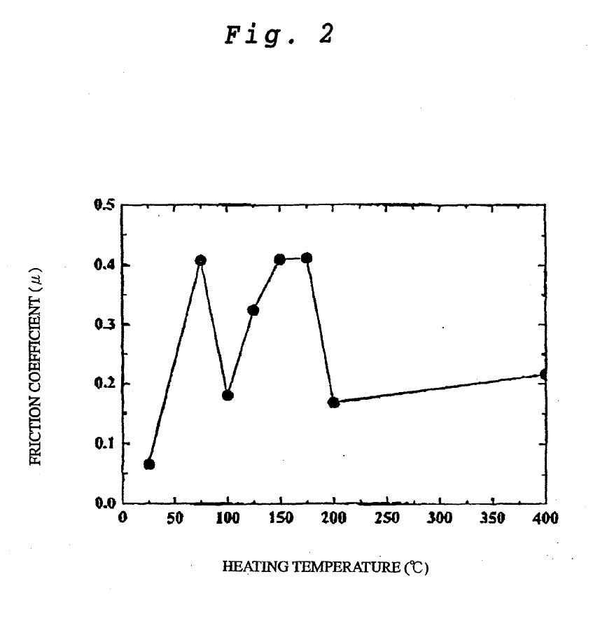

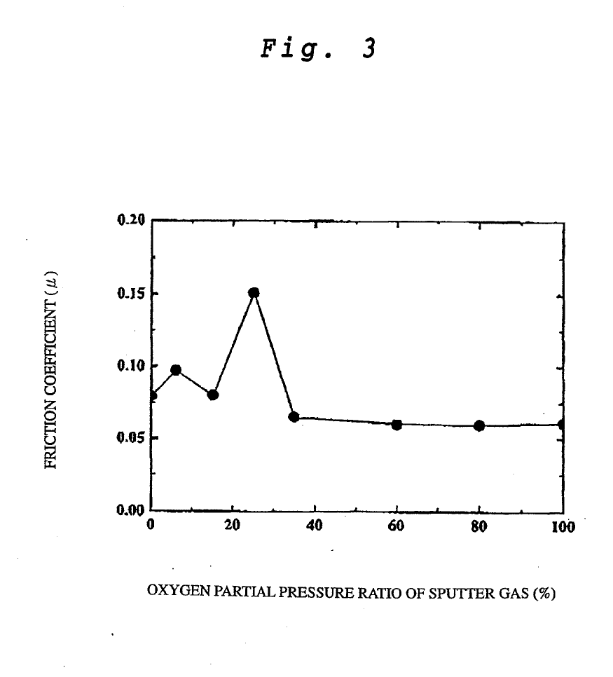

The change in friction coefficients of the films produced under various deposition conditions using the combinatorial coating apparatus described above was examined. FIG. 2 illustrates change in friction coefficient in the case where deposition was performed under 8 different substrate temperatures. FIG. 3 illustrates change in friction coefficient in the case where deposition was performed under 8 different oxygen partial pressures. Furthermore, change in friction coefficient could be examined in the case that deposition was performed under different substrate temperatures and different partial pressures. In this way, respective thin films deposited under different deposition conditions can be obtained in one vacuum evacuation process, and evaluation of various properties of the obtained coating films and optimization of the deposition conditions of the films can be easily performed.

### INDUSTRIAL APPLICABILITY

According to the invention of the application, a combinatorial deposition method and an apparatus thereof are provided, in which various conditions for deposition by sputtering and the like can be accurately controlled, and coating films can be efficiently produced under different deposition conditions.

1-5. (canceled)

6. A combinatorial deposition apparatus characterized in that the apparatus performs thin-film coating onto a substrate disposed in a vacuum, wherein a sample holder can hold two or more substrates, and each substrate can be moved to a deposition position or a cooling position, and sequentially only substrates to be coated are moved to the deposition position and subjected to deposition while substrates at the cooling position are cooled by a cooling mechanism, in one vacuum evacuation process.

7. The combinatorial deposition apparatus according to claim 6, characterized in that deposition is performed for the two or more substrates with different deposition conditions for each substrate.

8. The combinatorial deposition apparatus according to claim 6 characterized in that the two or more substrates can be moved to the deposition position or the cooling position by a rotation mechanism.

9. The combinatorial deposition apparatus according to claim 6 characterized in that even if a substrate at the deposition position is heated to 1000° C. or more, rise in temperature of substrates at the cooling position can be restrained within 100 K.

10. The combinatorial deposition apparatus according to claim 6 characterized in that a water- or liquid nitrogen-cooling mechanism is used.

11. The combinatorial deposition apparatus according to claim 6, characterized in that the apparatus is for deposition by sputtering, and deposition can be performed for two or more substrates with any one or more of the following deposition conditions: sputter gas pressure, sputter gas, partial pressure, sputter power value, substrate temperature, distance between the substrate and target, and sample bias, which are varied for each substrate, in one vacuum evacuation process.

12. The combinatorial deposition apparatus according to claim 11, characterized in that a valve for controlling the sputter gas pressure has a feedback function of changing conductance so that the pressure is equal to a prescribed value.

13. The combinatorial deposition apparatus according to claim 11, characterized in that the distance between the substrate and the target can be controlled by a straight-line introducing mechanism.

14. The combinatorial deposition apparatus according to claim 6, characterized in that a turbo molecular pump is provided as a vacuum evacuation mechanism.

15. The combinatorial deposition apparatus according to claim 6, characterized in that a substrate suited for the Suzuki friction test can be mounted.

16. The combinatorial deposition apparatus according to claim 6, characterized in that a position of the sample holder or a sputter source is variable, wherein deposition can be performed for a substrate cooled by the cooling mechanism.

17-19. (canceled)
